(19) United States
(12) Patent Application Publication
(10) Pub. No.: US 2015/0342052 A1
(43) Pub. Date: Nov. 26, 2015

(54) CIRCUIT SUBSTRATE, ELECTRONIC COMPONENT MOUNTING SUBSTRATE AND METHOD FOR PRODUCING CIRCUIT SUBSTRATE

(71) Applicant: SUMITOMO BAKELITE CO., LTD., Tokyo (JP)

(72) Inventors: Shigeyuki Yagi, Tokyo (JP); Mika Tsuda, Tokyo (JP)

(73) Assignee: SUMITOMO BAKELITE CO., LTD., Tokyo (JP)

(21) Appl. No.: 14/716,225

(22) Filed: May 19, 2015

(30) Foreign Application Priority Data
May 20, 2014 (JP) 2014-104134
May 20, 2014 (JP) 2014-104135

(51) Int. Cl. H05K 1/18; H05K 3/44; H05K 1/03

(52) U.S. Cl. CPC H05K 1/181; H05K 1/0373; H05K 3/44; H05K 2201/0209

(57) ABSTRACT

A circuit substrate 10 of the present invention includes a circuit layer 2. The circuit layer 2 includes a first terminal 21 in which a current should flow, a second terminal 22 in which a current larger than the current flowing in the first terminal 21 should flow and an insulating part 23. The insulating part 23 has a first portion 231 provided around the second terminal 22 and a second portion 232. An insulation property of the first portion 231 is higher than an insulation property of the second portion 232. The first portion 231 of the insulating part 23 is provided so as to surround an outer periphery of the second terminal 22. The circuit substrate 10 further includes a supporting substrate 1 provided on a side of a lower surface of the circuit layer 2.

### CROSS-REFERENCE TO RELATED APPLICATION

This application claims priories to Japanese Patent Application No. 2014-104134 filed on May 20, 2014 and Japanese Patent Application No. 2014-104135 filed on May 20, 2014 which are hereby expressly incorporated by reference herein in their entirety.

### TECHNICAL FIELD

The present invention relates to a circuit substrate, an electronic component mounting substrate and a method for producing a circuit substrate.

### BACKGROUND ART

A substrate which can deal with a large current by thickening a substrate thickness of a printed substrate (so called a “large current substrate”) has been known (for example, see patent document 1).

In such a large current substrate, it is assumed that a large current (for example, a current equal to or more than 20 A) flows. Thus, in order to reliably prevent a leakage of the large current, it is necessary to make a distance between current-carrying parts (terminals) for the large current sufficiently large (for example, a distance equal to or more than 10 mm) in a conventional large current substrate.

Generally, an electronic component having a low withstand voltage performance (such as a microcomputer) is also connected to the aforementioned printed substrate in which the large current should flow. Thus, the printed substrate in which the large current should flow also includes a current-carrying part (terminal) in which only a small current for the electronic component having the low withstand voltage performance should flow.

As described above, in the conventional printed substrate in which the large current should flow, it is necessary to make the distance between the current-carrying parts for the large current sufficiently large and further form the current-carry part in which only the small current should flow. For these reasons stated above, there is a problem that it is difficult to downsize the large current substrate in the prior art.

In addition, examples of a method for producing such a large current substrate in which the large current should flow include a method disclosed in patent document 2.

However, the method disclosed in the patent document 2 requires a step of laminating a plurality of non-flow resin plates, hardened resin plates, prepregs or the like; a step of providing metallic pieces in predetermined gaps and a step of press-heating it to produce the large current substrate. Thus, there is a problem that operations in the method are complicated and productivity of the large current substrate (circuit substrate) becomes low.

### RELATED ART DOCUMENTS

### Patent Documents

Patent document 1: JP 2011-216619A
Patent document 2: JP 2010-218797A

### SUMMARY OF INVENTION

### Problem to be Solved by the Invention

It is an object of the present invention to provide a circuit substrate which is downsized and in which a large current can flow, an electronic component mounting substrate which is downsized and in which a large current can flow, and a method for producing a substrate which can produce the circuit substrate at a high productivity.

### Means for Solving Problem

The above objection is achieved by the present invention including the following features (1) to (28).

(1) A circuit substrate comprising:

a circuit layer, the circuit layer including:

a first terminal in which a current should flow,

a second terminal in which a current larger than the current flowing in the first terminal should flow, and

an insulating part,

wherein the insulating part has a first portion provided around the second terminal and a second portion, and

wherein an insulation property of the first portion is higher than an insulation property of the second portion.

(2) The circuit substrate according to the above (1), wherein the first portion of the insulating part is provided so as to surround an outer periphery of the second terminal.

(3) The circuit substrate according to the above (1) or (2), wherein the first terminal is a terminal for connecting a microcomputer.

(4) The circuit substrate according to any one of the above (1) to (3), wherein the second terminal is a terminal for connecting an insulated gate bipolar transistor and/or a field effect transistor.

(5) The circuit substrate according to any one of the above (1) to (4), further comprising a supporting substrate provided on a side of a lower surface of the circuit layer.

(6) The circuit substrate according to the above (5), further comprising a high-insulating material layer provided between the supporting substrate and the circuit layer, and

wherein the supporting substrate is formed of a metallic material.

(7) The circuit substrate according to any one of the above (1) to (6), wherein a volume resistivity at a temperature of 25° C. of the first portion of the insulating part is in the range of 1×10⁷ to 1×10¹⁶ Ω·cm.

(8) The circuit substrate according to any one of the above (1) to (7), wherein the first portion of the insulating part is formed of a mixture material, the mixture material containing:

a hardened material containing a phenol resin and an epoxy resin as a constituent component thereof,

a first inorganic filler having an average particle size of 2 to 300 μm, and

a second inorganic filler having an average particle size of 0.1 to 9.0 μm.

(9) The circuit substrate according to any one of the above (1) to (8), wherein the second terminal penetrates through the circuit layer in a thickness direction thereof.

(10) The circuit substrate according to any one of the above (1) to (9), wherein a distance between the first terminal and the second terminal which are adjacent to each other is in the range of 0.05 to 5.0 mm.

(11) The circuit substrate according to any one of the above (1) to (10), wherein a width of the first portion in a planar view of the circuit substrate is equal to or more than 10 μm and less than 5 mm.

(12) An electronic component mounting substrate comprising:

a circuit substrate defined in any one of the above (1) to (11); and

electronic components respectively mounted to a first terminal and a second terminal of the circuit substrate.

(13) A method for producing a circuit substrate including a circuit layer, the circuit layer including a first terminal in which a current should flow, a second terminal in which a current larger than the current flowing in the first terminal should flow and an insulating part having a first portion and a second portion, the method comprising:

preparing a substrate having the second portion as a part of the insulating part, the first terminal and a hole formed therein;

inserting a metallic piece to be the second terminal into the hole of the substrate;

supplying a first high-insulating composition into a periphery of the metallic piece in the hole; and

hardening the first high-insulating composition and forming the first portion as another part of the insulating part to obtain the circuit layer,

wherein an insulation property of the first portion is higher than an insulation property of the second portion.

(14) The method for producing the circuit substrate according to the above (13), further comprising supplying a second high-insulating composition so that a supporting substrate contacts with the circuit layer through the second high-insulating composition after hardening the first high-insulating composition, and

hardening the second high-insulating composition to form a high-insulating material layer.

(15) The method for producing the circuit substrate according to the above (14), wherein the supporting substrate is formed of a metallic material.

(16) The method for producing the circuit substrate according to any one of the above (13) to (15), wherein inserting the metallic piece is carried out by inserting the metallic piece into the hole in a state that the metallic piece is temporarily fixed to a temporarily fixing member and contacting the temporarily fixing member with the substrate.

(17) The method for producing the circuit substrate according to the above (16), wherein inserting the metallic piece contains firmly contacting an entire of one surface of the substrate with the temporarily fixing member.

(18) The method for producing the circuit substrate according to the above (16) or (17), wherein the temporarily fixing member has a surface to be contacted with the metallic piece, and

wherein the surface to be contacted with the metallic piece is formed of a material having an adherence property.

(19) The method for producing the circuit substrate according to the above (18), wherein the material having the adherence property is a material whose adhesion strength with respect to an adherend reduces due to a hardening reaction.

(20) The method for producing the circuit substrate according to any one of the above (16) to (19), wherein the temporarily fixing member has a sheet-like shape.

(21) The method for producing the circuit substrate according to any one of the above (13) to (20), wherein inserting the metallic piece is carried out by fixing the metallic piece so that the metallic piece does not contact with the second portion of the insulating part.

(22) The method for producing the circuit substrate according to any one of the above (13) to (21), wherein the first terminal is a terminal for connecting a microcomputer.

(23) The method for producing the circuit substrate according to any one of the above (13) to (22), wherein the second terminal is a terminal for connecting an insulated gate bipolar transistor and/or a field effect transistor.

(24) The method for producing the circuit substrate according to the above (13) to (23), wherein the first high-insulating composition contains:

a phenol resin,

an epoxy resin,

a first inorganic filler having an average particle size of 2 to 300 μm, and

a second inorganic filler having an average particle size of 0.1 to 9.0 μm.

(25) The method for producing the circuit substrate according to any one of the above (13) to (24), wherein a distance between the first terminal and the second terminal which are adjacent to each other is in the range of 0.05 to 5.0 mm.

(26) The method for producing the circuit substrate according to any one of the above (13) to (25), wherein a width of the first portion of the insulating part in a planar view of the circuit substrate is equal to or more than 10 μm and less than 5 mm.

(27) A circuit substrate produced by a method defined in any one of the above (13) to (26).

(28) An electronic component mounting substrate comprising:

a circuit substrate defined in the above (27); and

electronic components respectively mounted to a first terminal and a second terminal of the circuit substrate.

### Effects of Invention

According to the present invention, it is possible to provide a circuit substrate which is downsized and in which a large current can flow. Further, it is possible to provide an electronic component mounting substrate which is downsized and in which a large current can flow. Furthermore, it is possible to provide a method for producing a circuit substrate which can produce the aforementioned circuit substrate at a high productivity.

### BRIEF DESCRIPTION OF DRAWINGS

FIG. 1 is a cross-sectional view schematically showing a preferred embodiment of a circuit substrate of the present invention.

FIG. 2 is a cross-sectional view schematically showing a preferred embodiment of an electronic component mounting substrate of the present invention.

FIG. 3 is a cross-sectional view schematically showing a preferred embodiment of a method for producing the circuit substrate and the electronic component mounting substrate of the present invention.

FIG. 4 is another cross-sectional view schematically showing the preferred embodiment of the method for producing the circuit substrate and the electronic component mounting substrate of the present invention.

### MODE FOR CARRYING OUT THE INVENTION

Hereinafter, a circuit substrate, an electronic component mounting substrate and a method for producing a circuit substrate of the present invention will be described in detail with reference to preferred embodiments shown in the accompanying drawings.

<<Circuit Substrate>>

First, description will be given to the circuit substrate of the present invention.

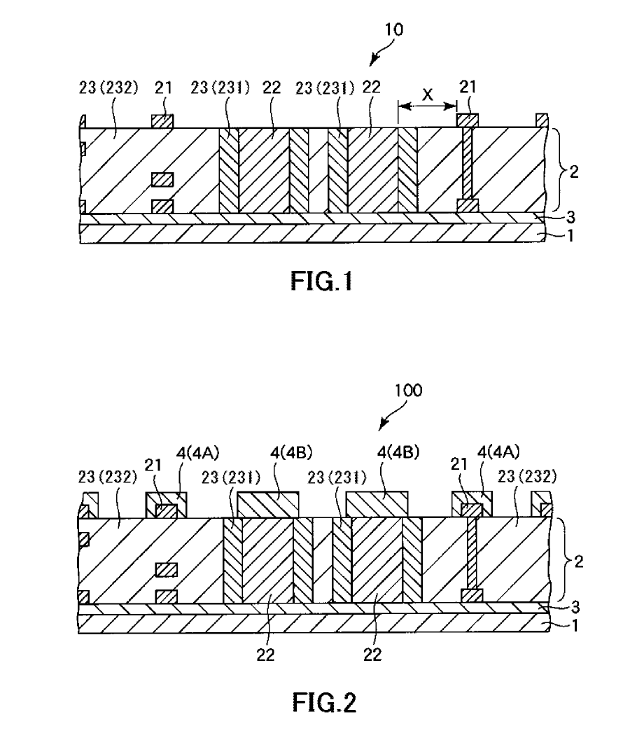

FIG. 1 is a cross-sectional view schematically showing a preferred embodiment of the circuit substrate of the present invention. It is noted that a part of a configuration of the present invention is enlarged and shown in the drawings referenced in this specification for the purpose of illustration and an actual dimension ratio or the like is not reflected to the drawings accurately.

A circuit substrate 10 shown in FIG. 1 includes a supporting substrate 1, a circuit layer 2 and a high-insulating material layer 3.

<Supporting Substrate>

The supporting substrate 1 has a function of supporting the circuit layer 2 described below.

Since the circuit substrate 10 includes such a supporting substrate 1, it is possible to improve a shape stability and a mechanical strength of the circuit substrate 10. For example, a metallic substrate may be preferably used as the supporting substrate 1.

By using the metallic substrate as the supporting substrate 1, it is possible to provide the aforementioned function of supporting the circuit layer 2 more efficiently as well as significantly improve a heat radiation property of the circuit substrate 10 as the whole. As a result, it is possible to significantly improve a heat resistance property and a reliability of the circuit substrate 10.

Examples of a constituent material for the supporting substrate (metallic substrate) 1 includes Cu, Au, Al and an alloy containing at least one of these materials.

A thickness of the supporting substrate 1 is not particularly limited to a specific value, but is preferably in the range of 0.5 to 5 mm, and more preferably in the range of 1 to 3 mm.

By setting the thickness of the supporting substrate 1 to fall within the above range, it is possible to efficiently prevent the thickness of the circuit substrate 10 from being thick more than necessary and more remarkably provide the aforementioned effect.

<Circuit Layer>

The circuit layer 2 includes at least one first terminal 21, at least one second terminal 22 and an insulating part 23. The circuit layer 2 serves as a layer forming an electronic circuit with these elements.

[First Terminal]

The first terminal 21 is a terminal for connecting (brazing and soldering) a first electronic component 4A with a brazing filler material such as a solder material. A current flowing in the first terminal 21 is smaller than a current flowing in the second terminal 22.

For example, a maximum value of the current flowing in the first terminal 21 when the first terminal 21 is used in an electronic component mounting substrate 100 is in the range of 1 mA to 10 A.

As described above, the first terminal 21 is a terminal in which a relatively small current should flow. Further, from the viewpoints of multi-layering or the like, it is preferable that a thickness of the first terminal 21 is relatively thin.

In particularly, the thickness of the first terminal 21 is not particularly limited to a specific value, but is preferably in the range of 10 to 100 μm, and more preferably in the range of 18 to 80 μm. By setting the thickness of the first terminal 21 to fall within the above range, it is possible to more remarkably provide the aforementioned effect.

Examples of a constituent material for the first terminal 21 include Cu, Ag, Al and an alloy containing at least one of these materials.

[Second Terminal]

The second terminal 22 is a terminal for connecting (brazing and soldering) a second electronic component 4B with a brazing filler material such as a solder material. The current flowing in the second terminal 22 is larger than the current flowing in the first terminal 21.

For example, a maximum value of the current flowing in the second terminal 22 when the second terminal 22 is used in the electronic component mounting substrate 100 is in the range of 20 to 150 A.

As describe above, the second terminal 22 is a terminal in which a relatively large current should flow. From the viewpoint of efficiently radiating heat (in particular, from the viewpoint of efficiently radiating heat generated from the second electronic component 4B connected to the second terminal 22 in the electronic component mounting substrate 100) and the viewpoint of reducing a heat generation of a conductor (in particular, from the viewpoint of reducing a conductor resistance generated when the relatively large current flows in the second terminal 22), it is preferable that the thickness of the second terminal 22 is relatively thick.

In more particularly, the thickness of the second terminal 22 is not particularly limited to a specific value, but is preferably in the range of 0.5 mm to 1 cm, and more preferably in the range of 1 to 5 mm. By setting the thickness of the second terminal 22 to fall within the above range, it is possible to more remarkably provide the aforementioned effect.

Further, it is preferable that the second terminal 22 penetrates through the circuit layer 2 in a thickness direction thereof. By forming the second terminal 22 so as to penetrate through the circuit layer 2 in the thickness direction thereof, it is possible to efficiently radiate heat (in particular, it is possible to efficiently radiate the heat generated from the second electronic component 4B connected to the second terminal 22 in the electronic component mounting substrate 100).

Examples of a constituent material for the second terminal 22 include Cu, Ag, Al and an alloy containing at least one of these materials.

In the circuit layer 2, a distance between the first terminal 21 and the second terminal which are adjacent to each other (a distance shown as “X” in FIG. 1) is preferably in the range of 0.05 to 5.0 mm, and more preferably in the range of 0.1 mm to 2.5 mm.

By setting the distance between the first terminal 21 and the second terminal 22 which are adjacent to each other to fall within the above range, it is possible to reliably prevent a generation of a problem such as a leakage and further downsize the circuit substrate 10.

[Insulating Part]

The insulating part 23 is provided between current-carrying parts of each terminal and has a function of preventing a short circuit or the like.

The insulating part 23 has a first portion (high-insulating area) 231 provided around the second terminal 22 and a second portion 232 as a portion other than the first portion 231. An insulation property of the first portion (high-insulating area) 231 is higher than an insulation property of the second portion 232.

As described above, the insulating part 23 has the first portion 231 having a relatively high insulation property and the second portion 232 other than the first portion 231. By using the insulating part 23 having such a configuration, it is possible to obtain the circuit substrate 10 having a terminal in which the large current should flow and reliably prevent the generation of the problem such as the leakage or the like even in the case where the distance between each terminal in the circuit substrate 10 becomes short. Thus, it is possible to provide the circuit substrate 10 which is downsized and in which the large current can flow. Further, in the case of forming the insulating part with a special insulating material having an insulation property higher than that of an insulating material generally used for a circuit substrate, a production cost for the circuit substrate generally increases. On the other hand, since the high-insulating area (the first portion 231) is selectively provided around the second terminal 22 and the other portion (the second portion 232) is formed of a relatively low cost material having an insulation property lower than that of the high-insulating area in the present invention, it is possible to suppress increase of a total producing cost for the circuit substrate 10 and provide the aforementioned effect.

In contrast, if the described condition for the insulation properties of the first portion 231 and the second portion 232 is not satisfied, the aforementioned superior effect cannot be provided.

For example, in the case where the insulating part 23 has no first portion (high-insulating area) 231 and the entire of the insulating part 23 is formed from only the second portion 232, it becomes difficult to reliably prevent the generation of the problem such as the leakage. In this regard, it is also possible to prevent the generation of the problem such as the leakage by enlarging the distance between each terminal. However, in this case, a size of the circuit substrate 10 increases.

Further, in the case where the insulating part has no second portion 232 and the entire of the insulating part 23 is formed from only the first portion (high-insulating area) 231, the producing cost for the circuit substrate 10 significantly increases. Furthermore, a mechanical strength of a hardened material of a first high-insulating composition 231′ forming the first portion 231 is low compared with the second portion 232. Thus, in the case where the entire of the insulating part 23 is formed from the hardened material of the first high-insulating composition 231′, a strength of the circuit substrate 10 as the whole cannot be ensure and there is possibility that a crack of the circuit substrate 10 or the like occurs.

In the case where a positional relationship between the first portion 231 and the second portion 232 is reversed, namely, in the case where the insulation property of the first portion 231 provided around the second terminal 22 is lower than the insulation property of the other portion (the second portion 232), it becomes difficult to prevent the generation of the problem such as the leakage. In this regard, it is also possible to prevent the generation of the problem such as the leakage by enlarging the distance between each terminal. However, in this case, the size of the circuit substrate 10 increases.

The first portion (high-insulating area) 231 may be provided at any position as long as the first portion 231 is provided around the second terminal 22. In the configuration shown in the drawing, the first portion (high-insulating area) 231 is provided so as to surround an outer periphery (an entire circumference) of the second terminal 22.

By using the insulating part 23 having such a configuration, it is possible to more reliably prevent the generation of the problem such as the leakage and efficiently suppress the increase of the producing cost for the circuit substrate 10. Further, since it is possible to further shorten the distance between each terminal, there is an advantage for further downsizing the circuit substrate 10. Furthermore, it is possible to make the current flowing in the second terminal 22 larger.

(First Portion (High-Insulating Area))

The insulation property of the first portion 231 is higher than the insulation property of the second portion 232.

A volume resistivity at a temperature of 25° C. of the first portion 231 is preferably in the range of 1×10⁷ to 1×10¹⁶ Ω·cm, and more preferably in the range of 1×10⁸ to 1×10¹⁵ Ω·cm.

By using the first portion 231 having such a volume resistivity, it is possible to more efficiently suppress the increase of the producing cost for the circuit substrate 10 and more reliably prevent the generation of the problem such as the leakage. Further, even in the case where a volume of the first portion 231 is small, it is possible to ensure a sufficient insulation property, and thereby further shortening the distance between each terminal. Thus, there is an advantage for further downsizing the circuit substrate 10. Furthermore, it is possible to make the current flowing in the second terminal 22 larger.

The volume resistivity can be measured with a method based on a double ring electrode method (JIS K6911).

The width of the first portion 231 (width in a planar view of the circuit substrate 10) is preferably equal to or more than 10 μm and less than 5 mm, and more preferably in the range of 100 to 500 μm.

By setting the width of the first portion 231 to fall within the above range, it is possible to more efficiently suppress the increase of the producing cost for the circuit substrate 10 and more reliably prevent the generation of the problem such as the leakage. Further, there is an advantage for further downsizing the circuit substrate 10. Furthermore, it is possible to make the current flowing in the second terminal 22 larger.

Although an constituent material for the first portion 231 is not particularly limited to a specific material as long as the specific magnitude relationship between the insulation properties of the first portion 231 and the second portion 232 described above is satisfied, it is preferable that the first portion 231 is formed of a mixture material containing a hardened material containing a phenol resin and an epoxy resin as a constituent component thereof, an inorganic filler (first inorganic filler) having an average particle size of 2 to 300 μm, and an inorganic filler (second inorganic filler) having an average particle size of 0.1 to 9.0 μm.

By forming the first portion 231 with such a mixture material, it is possible to more efficiently suppress the increase of the producing cost for the circuit substrate 10 and significantly improve the insulation property of the first portion 231.

Examples of the inorganic filler include a silicate such as a talc, a baked clay, an unbaked clay, a mica and a glass; an oxide such as a titanium oxide, an alumina, a silica and a fused silica; a carbonate such as a calcium carbonate, a magnesium carbonate and a hydrotalcite; a hydroxide such as an aluminum hydroxide, a magnesium hydroxide and a calcium hydroxide; a sulfate or a sulfite such as a barium sulfate, a calcium sulfate and a calcium sulfite; a borate such as a zinc borate, a barium metaborate, an aluminum borate, a calcium borate and a sodium borate; a nitride such as an aluminum nitride, a boron nitride, a silicon nitride and a carbon nitride; and a titanate such as a strontium titanate and a barium titanate. An inorganic filler having a low heat thermal conductivity (such as a silica) may be preferably used for more reliably preventing heat generated from the second electronic component 4B from adversely affecting other electronic components.

In the present invention, the average particle size refers to an average particle size on a volumetric basis unless otherwise specified.

The particle size can be measured by, for example, dispersing an alumina into water due to an ultrasonic treatment for 1 minute with a laser diffraction particle size analyzer “SALD-7000”.

The average particle size of the first inorganic filler is preferably in the range of 2 to 300 μm, more preferably in the range of 3 to 100 μm, and even more preferably in the range of 20 to 50 μm. By setting the average particle size of the first inorganic filler to fall within the above range, it is possible to more remarkably provide the aforementioned effect.

The average particle size of the second inorganic filler is preferably in the range of 0.1 to 9.0 μm, more preferably in the range of 1 to 8.0 μm, and even more preferably in the range of 3.0 to 5 μm. By setting the average particle size of the second inorganic filler to fall within the above range, it is possible to more remarkably provide the aforementioned effect.

A content percentage of the first inorganic filler in the first portion 231 it not particularly limited to a specific value, but is preferably in the range of 10 to 90 percent by mass, and more preferably in the range of 30 to 85 percent by mass.

By setting the content percentage of the first inorganic filler in the first portion 231 to fall within the above range, it is possible to decrease a linear expansion rate of the first portion 231, and thereby more efficiently reducing stress caused by a difference between the liner expansion rate of the first portion 231 and a liner expansion rate of the second portion 232.

A content percentage of the second inorganic filler in the first portion 231 is not particularly limited to a specific value, but is preferably in the range of 5 to 90 percent by mass, and more preferably in the range of 30 to 85 percent by mass.

By setting the content percentage of the second inorganic filler in the first portion 231 to fall within the above range, it is possible to decrease the linear expansion rate of the first portion 231, and thereby more efficiently reducing the stress caused by the difference between the liner expansion rate of the first portion 231 and the liner expansion rate of the second portion 232. Further, it becomes easier to add the first portion 231 to the hole 5 at the time of producing the circuit substrate 10.

A content percentage of a resin component (the first high-insulating composition 231′) in the first portion 231 is not particularly limited to a specific value, but is preferably in the range of 10 to 90 percent by mass, and more preferably in the range of 25 to 70 percent by mass. By setting the content percentage of the resin component in the first portion 231 to fall within the above range, it is possible to improve an adhesion strength of the first portion 231 with respect to the second portion 232.

In the case where the first portion 231 contains the epoxy resin, the epoxy resin preferably has at least one of an aromatic ring structure and an alicyclic structure (alicyclic carbocyclic ring structure).

By using the epoxy resin having such a structure, it is possible to significantly improve a heat resistance property and a reliability of the first portion 231.

Examples of the epoxy resin having the aromatic ring structure or the alicyclic structure include a bisphenol type epoxy resin such as a bisphenol A type epoxy resin, a bisphenol F type epoxy resin, a bisphenol S type epoxy resin, a bisphenol E type epoxy resin, a bisphenol M type epoxy resin, a bisphenol P type epoxy resin and a bisphenol Z type epoxy resin; a novolac type epoxy resin such as a phenol novolac type epoxy resin, a cresol novolac type epoxy resin and a tetraphenol group ethane type novolac type epoxy resin; an arylalkylene type epoxy resin such as a biphenyl type epoxy resin and a phenol aralkyl type epoxy resin having a biphenylene skeleton; and a naphthalene type epoxy resin. These epoxy resins may be used singly or in combination of two or more of them.

Further, from the viewpoints of further improving the heat resistance property, improving a breakdown voltage and the like, it is especially preferable that the naphthalene type epoxy resin is used as the epoxy resin. The naphthalene type epoxy resin refers to an epoxy resin having a naphthalene skeleton and two or more of glycidyl groups.

For example, a resin represented by the following formula (5), a resin represented by the following formula (6), a resin represented by the following formula (7) or a resin represented by the following formula (8) may be used as the naphthalene type epoxy resin. In the following formula (6), each of “m” and “n” is an integer of 1 to 7 and represents the number of substituent groups on a naphthalene ring independently. In the following formula (7), “Me” represents a methyl group and each of “l”, “m” and “n” is an integer equal to or more than 1. Further, each of “l”, “m” and “n” is preferably equal to or less than 10.

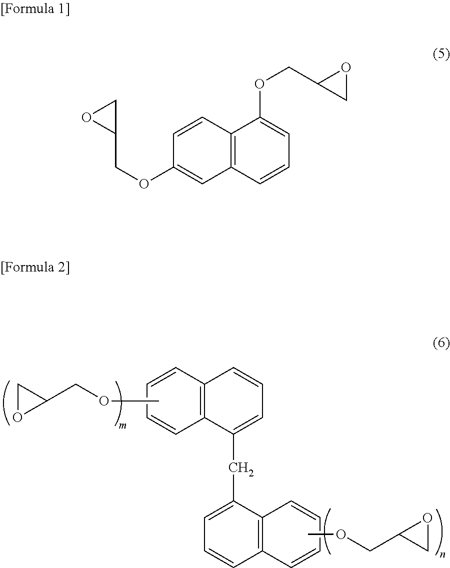

Each of “m” and “n” is an integer of 1 to 7.

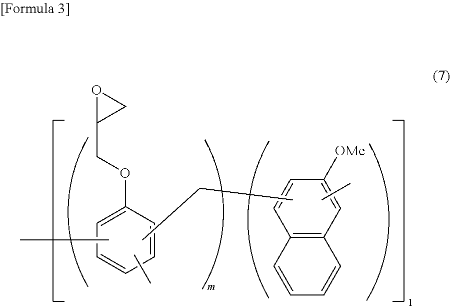

Each of “l”, “m” and “n” is a natural number equal to 1 or more than 1.

Among compounds represented by the above formula (6), compounds represented by the following formulas (6-1), (6-2) and (6-3) is more preferably used.

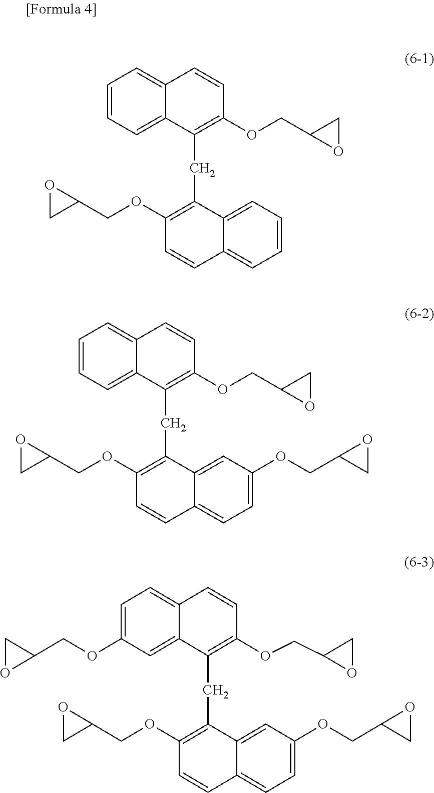 [SMILES: c1ccc2c(Cc3c(OCC4CO4)ccc4ccccc34)c(OCC3CO3)ccc2c1 ; c1ccc2c(Cc3c(OCC4CO4)ccc4ccc(OCC5CO5)cc34)c(OCC3CO3)ccc2c1 ; c1cc2ccc(OCC3CO3)c(Cc3c(OCC4CO4)ccc4ccc(OCC5CO5)cc34)c2cc1OCC1CO1]

As the naphthalene type epoxy resin, a naphthylene ether type epoxy resin represented by the following formula (8) may be also used.

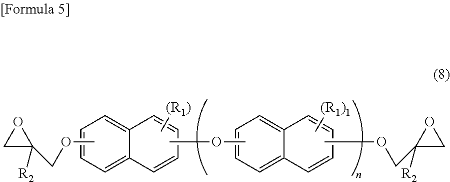

In the formula (8), “n” is an integer of 1 to 20, “1” is an integer of 1 to 2, each “R₁” is one of a hydrogen atom, a benzyl group, an alkyl group and an structure represented by the following formula (9) independently, and each “R₂” is a hydrogen atom or a methyl group independently.

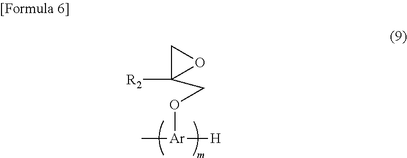

In the formula (9), each “Ar” is a phenylene group or a naphthylene group independently, each “R₂” is a hydrogen atom or a methyl group independently, and “m” is an integer of 1 to 2.

For example, among the naphthylene ether type epoxy resins represented by the above formula (8), a naphthylene ether type epoxy resin represented by the following (10) may be more preferably used.

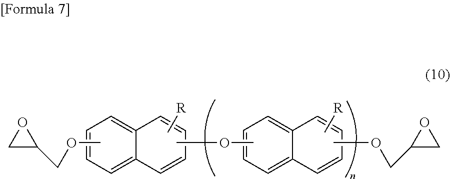

In the formula (10), “n” is an integer of 1 to 20, preferably an integer of 1 to 10, and more preferably an integer of 1 to 3. Each “R” is a hydrogen atom or a structure represented by the following formula (11) independently, and preferably the hydrogen atom.

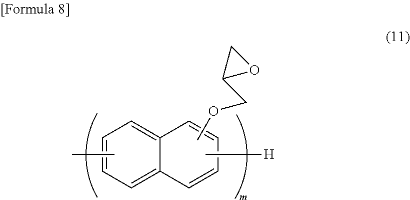

In the formula (11), “m” is an integer of 1 or 2.

For example, among the naphthylene ether type epoxy resins represented by the above formula (10), naphthylene ether type epoxy resins represented by the following formulas (12), (13), (14), (15) and (16) may be more preferably used.

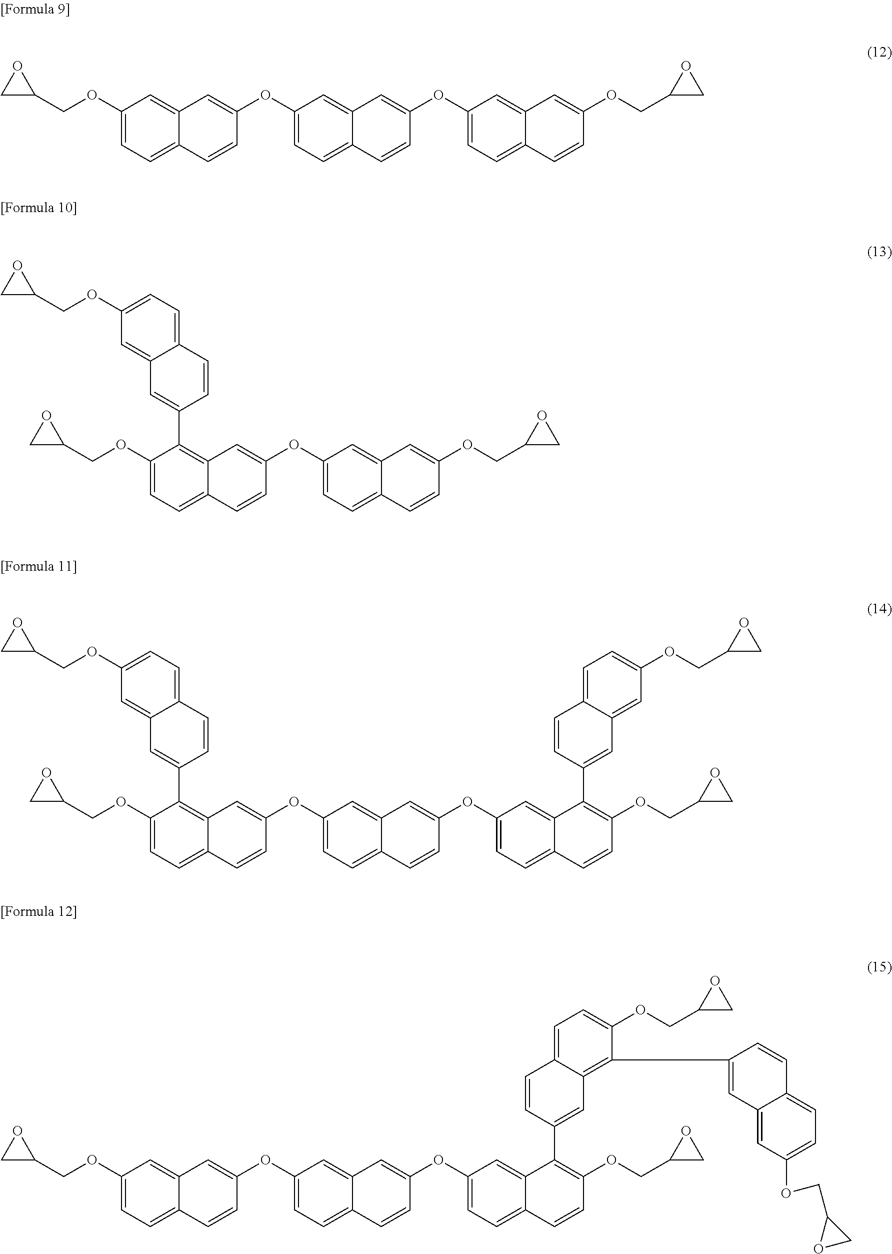 [SMILES: c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1 ; c1cc2ccc(-c3c(OCC4CO4)ccc4ccc(Oc5ccc6ccc(Oc7ccc8ccc(OCC9CO9)c(-c9ccc%10ccc(OCC%11CO%11)cc%10c9)c8c7)cc6c5)cc34)cc2cc1OCC1CO1 ; c1cc2ccc(Oc3ccc4ccc(Oc5ccc6ccc(OCC7CO7)c(-c7ccc8ccc(OCC9CO9)c(-c9ccc%10ccc(OCC%11CO%11)cc%10c9)c8c7)c6c5)cc4c3)cc2cc1OCC1CO1]

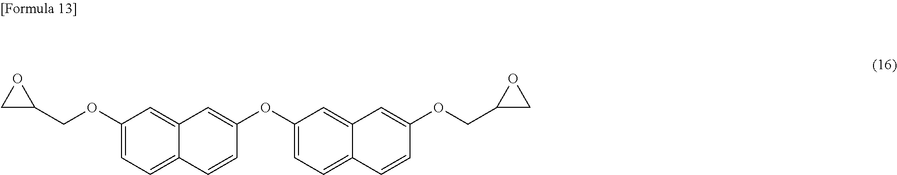

Further, although a novolac type resin, a resol type resin or the like may be used as the phenol resin, a novolac resin is preferably used as the phenol resin.

By using such a phenol resin, it is possible to improve a heat resistance property of a obtained high-insulating material. As a result, a volume shrinkage rate of a hardened material of the obtained high-insulating material becomes smaller and a producing stability of the obtained high-insulating material is significantly improved. Further, a melting point of the phenol resin is preferably in the range of 80 to 100° C., and more preferably in the range of 85 to 95° C.

An equivalent ratio of the number of functional groups of the phenol resin, an acid anhydride or an amine-based curing agent with respect to the number of the epoxy groups of the epoxy resin in the resin component (the first high-insulating composition 231′) constituting the first portion 231 is not particularly limited to a specific value, but is preferably in the range of 0.3 to 1.5, and more preferably in the range of 0.5 to 1.2.

By setting the equivalent ratio to fall within the above range, the obtained high-insulating material can have a more dense cross-liked structure. As a result, the heat resistance property and a humidity resistance property of the high-insulating material are improved.

A liner expansion coefficient (liner expansion rate) at a temperature of 25° C. of the constituent material for the first portion 231 is preferably equal to or less than 30 ppm, and more preferably equal to or less than 20 ppm.

Since the first portion 231 is provided around the second terminal 22 in which the large current should flow, a temperature of the first portion 231 is likely to increase and a temperature change of the first portion 231 is also large. In the case where the liner expansion coefficient (liner expansion rate) of the constituent material for the first portion 231 is sufficiently small as describe above, it is possible to more efficiently prevent a generation of a detachment or a crack in the circuit substrate 10 (for example, at a boundary surface between the second terminal 22 and the first portion 231) or in the electronic component mounting substrate 100 (for example, at a connecting portion between the electronic component and the terminal), and thereby significantly improving the durability and the reliability of the circuit substrate 10 and the electronic component mounting substrate 100.

A glass-transition temperature (Tg) of the constituent material for the first portion 231 is preferably equal to or more than 120° C., and more preferably equal to or more than 140° C.

By setting the glass-transition temperature (Tg) of the resin material constituting the first portion 231 to fall within the above range, it is possible to improve the heat resistance property of the circuit substrate 10 and the electronic component mounting substrate 100.

In the present invention, the circuit substrate includes at least one first portion 231. In the configuration shown in the drawing, the circuit substrate 10 includes a plurality of first portions 231.

In this case, the plurality of first portions 231 may have the same condition each other or respectively have different conditions.

(Second Portion)

Although the second portion 232 has a sufficient insulation property, the insulation property of the second portion 232 is lower than the insulation property of the first portion 231.

By using the insulating part 23 having such a second portion 232, it is possible to efficiently suppress the increase of the producing cost for the circuit substrate 10.

A volume resistivity at a temperature of 25° C. of the second portion 232 is preferably in the range of 1×10⁶ to 1×10¹⁴ Ω·cm, and more preferably in the range of 1×10⁷ to 1×10¹² Ω·cm.

By setting the volume resistivity at the temperature of 25° C. of the second portion 232 to fall within the above range, it is possible to sufficiently prevent the generation of the problem such as the leakage and further reduce the producing cost for the circuit substrate 10. In addition, since it is possible to further shorten the distance between each terminal, there is an advantage for further downsizing the circuit substrate 10.

A constituent material for the second portion 232 is not particularly limited to a specific material as long as the specific magnitude relationship between the insulation properties of the first portion 231 and the second portion 232 described above is satisfied. For example, a hardened material (such as FR4 and FR5) containing a glass fiber may be used as the constituent material for the second portion 232. UL/ANSI type FR4 is a hardened material containing an epoxy resin as a main resin thereof, a glass fiber and an inorganic filler. A contained amount of the epoxy resin is equal to or more than 50 percent by mass with respect to the total of the hardened material except the inorganic filler. In the case of using the inorganic filler, a contained amount of the inorganic filler is 45 percent by mass with respect to the total of the hardened material. Further, it is preferable that the second portion 232 is formed of mixture material other than FR4. The mixture material contains a resin component containing an epoxy resin as a main component thereof and at least one of a phenol resin, an acid anhydride and an amine-based hardened material, a glass cloth, a first inorganic filler having an average particle size of 2 to 300 μm and a second inorganic filler having an average particle size of 0.1 to 9.0 μm. By forming the second portion 232 with such a material, it is possible to improve the mechanical strength of the circuit substrate 10 as the whole.

A thickness of the circuit layer 2 including the first terminal 21, the second terminal 22 and the insulating part 23 described above is not particularly limited to a specific value, but is preferably in the range of 0.5 to 5 mm, and more preferably in the range of 1 to 3 mm.

<High-Insulating Material Layer>

In the configuration shown in the drawing, the high-insulating material layer 3 is provided between the supporting substrate 1 and the circuit layer 2.

As shown in the drawing, by providing the high-insulating material layer 3 between the supporting substrate 1 and the circuit layer 2, it is possible to reliably prevent the generation of the problem such as the leakage of current from surfaces of the first terminal 21 and the second terminal 22.

A volume resistivity at a temperature of 25° C. of the high-insulating material layer 3 is preferably in the range of 1×10⁶ to 1×10¹⁵ Ω·cm, and more preferably in the range of 1×10⁸ to 1×10¹⁴ Ω·cm.

By setting the volume resistivity at the temperature of 25° C. of the high-insulating material layer 3 to fall within the above range, it is possible to more efficiently suppress the increase of the producing cost for the circuit substrate 10 and more reliably prevent the generation of the problem such as the leakage. Further, since it is possible to ensure a sufficient insulation property even in the case where a thickness of the high-insulating material layer 3 is thin, there is an advantage for downsizing the circuit substrate 10.

A constituent material for the high-insulating material layer 3 is not particularly limited to a specific material. For example, the same material as the constituent material for the first portion 231 described above may be used as the constituent material for the high-insulating material layer 3.

The thickness of the high-insulating material layer 3 is not particularly limited to a specific value, but is preferably in the range of 40 to 300 μm, and more preferably in the range of 80 to 200 μm.

By setting the thickness of the high-insulating material layer 3 to fall within the above range, it is possible to reliably prevent the generation of the problem such as the leakage and improve the heat radiation property of the circuit substrate 10 as the whole in the case where the supporting substrate 1 is formed of the metallic material.

Although the high-insulating material layer 3 is provided on an entire of a lower surface of the supporting substrate 1 in the configuration shown in the drawing, the high-insulating material layer 3 may be provided on only a part of the lower surface of the supporting substrate 1. For example, the high-insulating material layer 3 may be selectively provided on a portion on a lower side (lower surface in the drawing) of the circuit layer 2, on which the current-carrying part is provided.

<<Electronic Component Mounting Substrate>>

Next, description will be given to the electronic component mounting substrate of the present invention.

FIG. 2 is a cross-sectional view schematically showing a preferred embodiment of the electronic component mounting substrate of the present invention. As shown in FIG. 2, the electronic component mounting substrate 100 can be obtained by mounting the electronic component 4 (the first electronic component 4A, the second electronic component 4B) on the aforementioned circuit substrate 10. Namely, in the electronic component mounting substrate 100, the first electronic component 4A is connected to the first terminal 21 and the second electronic component 4B is connected to the second terminal 22.

With this configuration, it is possible to provide the electronic component mounting substrate 100 which is downsized and in which the large current can flow.

<First Electronic Component>

The first electronic component 4A is an electronic component to be connected to the first terminal 21.

A current flowing in the first electronic component 4A is smaller than a current flowing in the second electronic component 4B.

Concrete examples of the first electronic component 4A include an IC chip such as a microcomputer, a ceramic capacitor and a chip resistor. Among them, the electronic component mounting substrate 100 preferably includes the microcomputer as the first electronic component 4A.

With this configuration, it becomes possible to mount the first electronic component 4A in which a small current should flow and the second electronic component 4B in which a larger current should flow on the same substrate. Thus, it is possible to shorten a length of a wiring, and thereby further downsizing the electronic component mounting substrate 100. Further, since the length of the wiring becomes shorter, it is possible to improve a responsiveness of an electric signal and reduce a noise of the electric signal.

In the configuration shown in the drawing, the electronic component mounting substrate 100 includes a plurality of first electronic components 4A. These first electronic components 4A may be the same or different from each other.

<Second Electronic Component>

The second electronic component 4B is an electronic component to be connected to the second terminal 22.

The current flowing in the second electronic component 4B is larger than the current flowing in the first electronic component 4A.

Concrete examples of the second electronic component 4B include a so-called heat-generating component (an electronic component having an amount of heat generation larger than that of the first electronic component 4A) such as an insulated gate bipolar transistor, a field effect transistor and a transformer. Among them, the electronic component mounting substrate 100 preferably includes the insulated gate bipolar transistor and/or the field effect transistor as the second electronic component 4B.

With this configuration, it is possible to efficiently transfer heat generated from the heat-generating component toward a lower direction (a thickness direction) of the circuit substrate 10.

In the configuration shown in the drawing, the electronic component mounting substrate 100 includes a plurality of second electronic components 4B. These second electronic components 4B may be the same or different from each other.

A use application of the electronic component mounting substrate 100 is not limited. For example, the electronic component mounting substrate 100 may be used for an electronic device such as a power semiconductor device, an LED illumination, an inverter device or the like.

The inverter device refers to a device for electrically generating alternating-current power from direct-current power (a device having a reverse converting function of converting the direct-current power to the alternating-current power). The power semiconductor device is generally called as a power device having a high-voltage characteristic, a large-current characteristic, a high-speed and high-frequency characteristic compared with a normal semiconductor element. Examples of the power semiconductor device include a rectifier diode, a power transistor, a power MOSFET, an insulating gate bipolar transistor (IGBT), a thyristor, a gate turn-off thyristor (GTO) and a triac.

<<Method for Producing Circuit Substrate and Electronic Component Mounting Substrate>>

Next, description will be given to the method for producing the circuit substrate and the electronic component mounting substrate of the present invention.

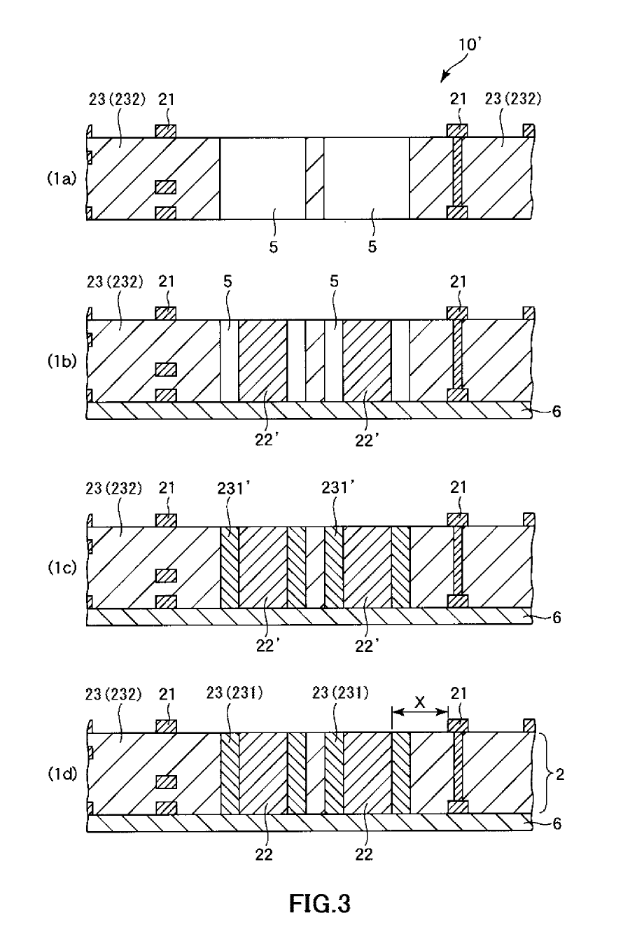

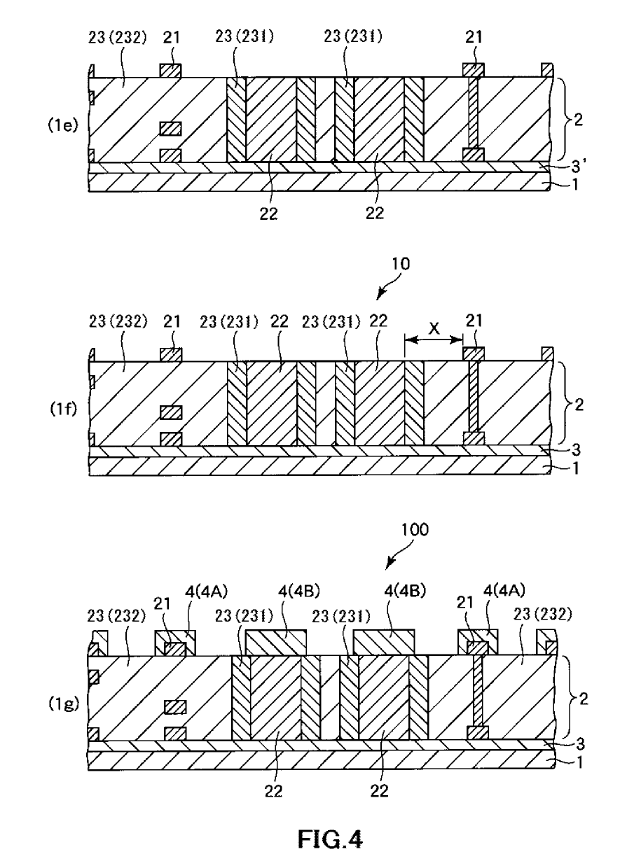

Each of FIGS. 3 and 4 is a cross-sectional view schematically showing a preferred embodiment of the method for producing the circuit substrate and the electronic component mounting substrate of the present invention.

As shown in FIGS. 3 and 4, the method for producing the circuit substrate and the electronic component mounting substrate according to this embodiment includes the following steps (1a) to (1g). The method includes a substrate preparing step (a printed substrate preparing step) (1a) for preparing a printed substrate 10′ having the second portion 232 as a part of the insulating part 23, the first terminal 21 and the hole 5 formed in the printed substrate 10′, a metallic piece inserting step (1b) for inserting a metallic piece 22′ into the hole 5 of the printed substrate 10′, a first high-insulating composition supplying step (1c) for supplying the high-insulating composition (the first high-insulating composition) 231′ into a periphery of the metallic piece 22′ in the hole 5, a first hardening step (1d) for hardening the high-insulating composition 231′ and forming the first portion (the high-insulating are) 231 to obtain the circuit layer 2, a second high-insulating composition supplying step (1e) for supplying another high-insulating composition (second high-insulating composition) 3′ so that the supporting substrate contacts with the circuit layer 2 through the high-insulating composition (the second high-insulating composition) 3′, a second hardening step (1f) for hardening the high-insulating composition (the second high-insulating composition) 3′ to form the high-insulating material layer 3, and an electronic component connecting step (1g) for connecting the electronic components 4 (the first electronic component 4A and the second electronic component 4B) to the first terminal 21 and the second terminal 22.

With this method, it is possible to efficiently obtain the circuit substrate 10 including the first terminal 21 in which the current should flow, the second terminal 22 in which the current larger than the current flowing in the first terminal 21 should flow, the second portion 232 as a part of the insulating part 23, and the first portion 231 provided around the second terminal 22 and having the insulation property larger than the insulation property of the second portion 232. The circuit substrate 10 having such a configuration can reliably prevent the generation of the problem such as the leakage even in the case where the circuit substrate 10 includes the terminal in which the large current should flow and the distance between each terminal become smaller. Thus, it is possible to provide the circuit substrate 10 which is downsized and in which the large current can flow. Further, if the insulating part 23 is formed of only a special insulating material having an insulation property larger than an insulation property of a material generally used for a circuit substrate, a producing cost for the circuit substrate generally increases. In contrast, since the first portion (the high-insulating area) 231 is selectively provided around the second terminal 22 and the other portion (the second portion) 232 is formed of a relatively low cost material having the insulation property lower than that of the first portion 231 in the present invention, it is possible to suppress the increase of the producing cost for the circuit substrate 10 as the whole and provide the aforementioned effect.

<Printed Substrate Preparing Step>

First, the printed substrate 10′ having the second portion 232 as a part of the insulating part 23, the first terminal 21 and the hole 5 formed in the printed substrate 10′ is prepared (1a).

The printed substrate 10′ can be produced with any method. For example, the existing method can be used for producing the printed substrate 10′.

The second portion 232 is a part of the insulating part 23. The second portion 232 is provided so as to surround at least an outer periphery of the first terminal 21 existing inside the printed substrate 10′.

The insulation property of the second portion 232 is lower than the insulation property of the first portion 231.

By using the second portion 232 having such a configuration, it is possible to reliably prevent the generation of the problem such as the leakage and efficiently suppress the increase of the producing cost for the circuit substrate 10.

The first terminal 21 is the terminal for connecting (brazing and soldering) the first electronic component 4A with the brazing filler material such as the solder material.

In the subsequent step, the metallic piece 22′ is inserted into the hole 5 and the high-insulating composition (the first high-insulating composition) 232′ is supplied into the hole 5 to form the second terminal 22 and the first portion 231 in the hole 5.

A thickness of the printed substrate 10′ is not particularly limited to a specific value, but is preferably in the range of 0.5 to 5 mm, and more preferably in the range of 1 to 3 mm.

<Metallic Piece Inserting Step>

Next, the metallic piece 22′ to be the second terminal 22 is inserted into the hole 5 of the printed substrate 10′ (1b).

Although the metallic piece 22′ may be inserted into the hole 5 singly, the metallic piece 22′ temporarily fixed on a temporarily fixing member 6 is inserted into the hole 5 so that the temporarily fixing member 6 contacts with the printed substrate 10′ in the configuration shown in the drawing.

By using such a temporarily fixing member 6 in this manner, a position adjustment of the metallic piece 22′ become easier. Thus, it is possible to significantly improve the productivity of the circuit substrate 10. Especially, in the case of using a plurality of metallic pieces 22′, this effect becomes more remarkable.

In particular, an entire of one surface of the printed substrate 10′ is temporarily fixed to the temporarily fixing member 6 so that the entire of the one surface of the printed substrate 10′ firmly contacts with the temporarily fixing member 6 in the configuration shown in the drawing.

By temporarily fixing the temporarily fixing member 6 on the printed substrate 10′ in this manner, it is possible to more efficiently prevent a generation of an undesired position gap of the metallic piece 22′. Thus, there is an advantage for, for example, improving a yield rate of the circuit substrate 10 and the reliability of the produced circuit substrate 10.

For example, as the temporarily fixing member 6, a member whose surface contacting with the metallic piece 22′ is formed of a material having an adherence property is preferably used.

By using such a temporarily fixing member 6, it is possible to preferably carry out the inserting and the position adjustment of the metallic piece 22′ in this step and easily remove the temporarily fixing member 6 in the subsequent step.

As the material having the adherence property, a wide variety of gluing agents may be used. Further, it is preferably to use a material whose adherence property is loss and whose adhesion strength with respect to an adherend reduces due to a hardening reaction as the material having the adherence property. By using the temporarily fixing member 6 using such a cohesive material, it is possible to further improve the productivity of the circuit substrate 10.

Further, as a constituent material for the temporarily fixing member 6, the same composition as a composition of the second high-insulating composition 3′ described below may be used.

By forming the temporarily fixing member 6 with the same composition as that of the second high-insulating composition 3′, it is possible to omit a process for removing the temporarily fixing member 6 with sufficiently providing the function as the temporarily fixing member 6 as described above. As a result, it is possible to significantly improve the productivity of the circuit substrate 10 and the electronic component mounting substrate 100.

In the configuration shown in the drawing, the temporarily fixing member 6 has a sheet-like shape. By forming the temporarily fixing member 6 in a form of the sheet-like shape, it is possible to improve a handling property (ease of handling) of the temporarily fixing member 6, and thereby further improving the productively of the circuit substrate 10.

In the configuration shown in the drawing, this step is carried out by inserting the metallic piece 22′ into the hole 5 so that the metallic piece 22′ does not contact with the second portion 232.

By inserting the metallic pieces 22′ into the hole 5 in this manner, it is possible to form the first portion 231 so as to surround the outer periphery (the entire circumference) of the second terminal 22 in the subsequent step. As a result, it is possible to more reliably prevent the generation of the problem such as the leakage. Further, since it is possible to further shorten the distance between each terminal, there is an advantage for further downsizing the circuit substrate 10. Furthermore, it is possible to make the current flowing in the second terminal 22 larger.

<First High-Insulating Composition Supplying Step>

Next, the first high-insulating composition 231′ is supplied into the periphery of the metallic piece 22′ in the hole 5 (1c).

A method for supplying the first high-insulating composition 231′ is not particularly limited to a specific method. For example, it is possible to use a wide variety of printing methods such as a screen printing method and an ink-jet printing method for supplying the first high-insulating composition 231′.

For example, a composition containing a hardening resin may be used as the first high-insulating composition 231′. Further, for example, the epoxy resin and the phenol resin as described above may be preferably used as the hardening resin.

The first high-insulating composition 231′ may further contain a hardening agent. By adding the hardening agent to the first high-insulating composition 231′, it is possible to more promptly progress a hardening reaction in the subsequent hardening step (the first hardening step) described below, and thereby significantly improving the productivity of the circuit substrate 10. Further, since the hardening reaction can be preferably progressed, it is possible to more reliably improve the heat resistance property, the mechanical strength or the like of the circuit substrate 10.

Examples of the hardening agent (hardening catalyst) include an organometallic salt such as zinc naphthenate, cobalt naphthenate, tin octylate, cobalt octylate, cobalt bisacetylacetonate (II) and cobalt trisacetylacetonate (III); an amine-based hardening agent such as dicyandiamide, diethylene triamine, triethylene tetramine, metaxylylene diamine, diamino diphenylmethane, diamino diethyl diphenylmethane, metaphenylene diamine, diamino diphenylsulfone, isophorone diamine, norbornene diamine, triethylamine, tributylamine and diazabicyclo[2,2,2]octane; an imidazole-based hardening agent such as 2-phenyl-imidazole, 2-phenyl-4-methylimidazole, 2-ethyl-4-methylimidazole, 2-ethyl-4-ethylimidazole, 2-phenyl-4-methyl-5-hydroxyimidazole and 2-phenyl-4,5-dihydroxyimidazole; an organic phosphorous compound such as triphenylphosphine, tri-p-tolylphosphine, tetraphenylphosphonium•tetraphenylborate, triphenylphosphine•triphenylborane and 1,2-bis-(diphenylphosphino)ethane; a phenol compound such as a phenol, a bisphenol A and a nonyl phenol; an organic acid such as an acetic acid, a benzoic acid, a salicylic acid and a paratoluenesulfonic acid; and a derivant thereof (such as an acid anhydride). These compounds may be used singly or in the combination of two or more of them as the hardening agent.

Among them, the amine-based hardening agent or the imidazole-based hardening agent is preferably used because they have a superior adherence property and can react at a relatively low temperature and it is possible to obtain a hardened material having a superior heat resistance property by using one of them.

An contained amount of the hardening catalyst in the first high-insulating composition 231′ is not particularly limited to a specific value, but is preferably in the range of 0.05 to 3.0 parts with respect to 100 parts of a total solid content in the first high-insulating composition 231′, for example.

The first high-insulating composition 231′ may further contain a coupling agent. By adding the coupling agent to the first high-insulating composition 231′, in the case where the first high-insulating composition 231′ contains, for example, the epoxy resin and the silica, it is possible to improve a wettability of the epoxy resin with respect to the silica, and thereby significantly improving the mechanical strength or the like of the first portion 231 formed by using the first high-insulating composition 231′.

As the coupling agent, a wide variety of materials known as a coupling agent may be used. In particular, it is preferably to use one or more coupling agents selected from the group consisting of an epoxy silane coupling agent, a cationic silane coupling agent, an amino silane coupling agent, a titanate-based coupling agent and a silicone oil-based coupling agent.

An additive amount of the coupling agent is not particularly limited to a specific value, but is preferably in the range of 0.05 to 3 parts, and more preferably in the range of 0.1 to 2 parts with respect to 100 parts of silica. By setting the additive amount of the coupling agent to fall within the above range, it is possible to more remarkably provide the aforementioned effect.

The first high-insulating composition 231′ may further contain a wide variety of additive agents such as an antioxidizing agent and a leveling agent.

Further, the first high-insulating composition 231′ may contain a volatile component (solvent component). In this case, a content percentage of the volatile component in the first high-insulating composition 231′ is preferably equal to or less than 1.0 percent by mass, and more preferably equal to or less than 0.5 percent by mass.

By setting the content percentage of the volatile component in the first high-insulating composition 231′ to fall within the above range, it is possible to omit or simplify a process for removing the volatile component in the subsequent step, and thereby significantly improving the productivity of the circuit substrate 10.

A viscosity (a viscosity measured by a measuring method with a dynamic viscoelasticity measuring apparatus) at a temperature of 25° C. of the first high-insulating composition 231′ is preferably in the range of 0.1 to 1000 Pa·s, and more preferably in the range of 10 to 500 Pa·s.

By setting the viscosity at the temperature of 25° C. of the first high-insulating composition 231′ to fall within the above range, it is possible to significantly improve a handling property (ease of handling) of the first high-insulating composition 231′, and thereby significantly improving the productivity of the circuit substrate 10. Further, it is possible to effectively prevent an undesired air bubble from being entrapped in the first portion 231, the vicinity of a boundary surface between the first terminal 21 and the first portion 231, the vicinity of a boundary surface between the first portion 231 and the second portion 232 or the like, and thereby significantly improving the reliability of the circuit substrate 10.

<First Hardening Step>

Next, the high-insulating composition 231′ is hardened to form the first portion (high-insulating area) 231 (1d).

By hardening the high-insulating composition 231′, it is possible to obtain the circuit layer 2 including the insulating part 23 having the first portion 231 and the second portion 232, the first terminal 21 and the second terminal 22 formed by the metallic piece 22′.

The insulation property of the first portion 231 formed in this step is larger than the insulation property of the second portion 232.

Although a hardening method in this step depends on the constituent material for the first high-insulating composition 231′, the hardening of the first high-insulating composition 231′ is generally carried out by heating in the case where the first high-insulating composition 231′ contains a thermosetting resin.

A heating temperature in this step depends on the composition of the first high-insulating composition 231′ or the like, but is preferably in the range of 60 to 200° C., and more preferably in the range of 80 to 180° C.

By setting the heating temperature to fall within the above range, it is possible to promptly progress the hardening reaction of the first high-insulating composition 231′, and thereby significantly improving the productivity of the circuit substrate 10. Further, it is possible to preferably progress the hardening reaction, and thereby more reliably improving the heat resistance property, the mechanical strength or the like of the circuit substrate 10.

A heating time (duration) in this step depends on the composition of the first high-insulating composition 231′ or the like, but is preferably in the range of 3 seconds to 3 hours, and more preferably in the range of 10 seconds to 1 hour.

By setting the heating time to fall within the above range, it is possible to sufficiently improve the productivity of the circuit substrate 10 and more preferably progress the hardening reaction, and thereby more reliably improving the heat resistance property, the mechanical strength or the like of the circuit substrate 10.

<Second High-Insulating Composition Supplying Step>

Next, the supporting substrate 1 is contacted with the circuit layer 2 through the high-insulating composition (the second high-insulating composition) 3′ in a state that the temporarily fixing member 6 is removed (1e).

In this step, the second high-insulating composition 3′ is applied onto a surface of one of the supporting substrate 1 and the circuit layer 2 and then the supporting substrate 1 and the circuit layer 2 are gotten closer to each other to contact the supporting substrate 1 with the circuit layer 2 through the second high-insulating composition 3′. Alternatively, the second high-insulating composition 3′ may be applied onto surfaces (surfaces facing with each other) of the supporting substrate 1 and the circuit layer 2 and then the supporting substrate 1 and the circuit layer 2 may be gotten closer to each other to contact the supporting substrate 1 with the circuit layer 2 through the second high-insulating composition 3′.

Alternatively, the supporting substrate 1 may be contacted with the circuit layer 2 through the second high-insulating composition 3′ by arranging the supporting substrate 1 and the circuit layer 2 so as to form a gap having a predetermined width therebetween and injecting the second high-insulating composition 3′ into the gap.

A method for applying the second high-insulating composition 3′ is not particularly limited to a specific method. For example, a wide variety of printing methods may be used for applying the second high-insulating composition 3′.

For example, as the second high-insulating composition 3′, the same composition described as the first high-insulating composition 231′ may be used. By using such a second high-insulating composition 3′, it is possible to provide the same effect described above.

<Second Hardening Step>

Next, the second high-insulating composition 3′ is hardened (1f).

By hardening the second high-insulating composition 3′, it is possible to form the high-insulating material layer 3 and connect the supporting substrate 1 with the circuit layer 2 through the high-insulating material layer 3 to obtain the circuit substrate 10.

Although the high-insulating material layer 3 is provided on the entire of the lower surface of the supporting substrate 1 in the configuration shown in the drawing, the high-insulating material layer 3 may be provided on only a part of the lower surface of the supporting substrate 1. For example, the high-insulating material layer 3 may be selectively provided on a portion on the lower side (lower surface in the drawing) of the circuit layer 2, on which the current-carrying part is provided. For example, such a configuration can be formed by using a substrate having a concave portion at a portion corresponding to the portion on which the high-insulating material layer 3 should be provided as the supporting substrate 1 in the above step and carrying out the aforementioned second high-insulating material supplying step so that another portion than the concave portion of the supporting substrate 1 firmly contacts with the circuit layer 2.

Although a hardening method in this step depends on the constituent material for the second high-insulating composition 3′, the hardening of the second high-insulating composition 3′ is generally carried out by heating in the case where the second high-insulating composition 3′ contains a thermosetting resin.

A heating temperature in this step depends on the composition of the second high-insulating composition 3′ or the like, but is preferably in the range of 60 to 200° C., and more preferably in the range of 80 to 180° C.

By setting the heating temperature to fall within the above range, it is possible to promptly progress the hardening reaction of the second high-insulating composition 3′, and thereby significantly improving the productively of the circuit substrate 10. Further, it is possible to preferably progress the hardening reaction, and thereby more reliably improving the heat resistance property, the mechanical strength or the like of the circuit substrate 10.

A heating time (duration) in this step depends on the composition of the second high-insulating composition 3′ or the like, but is preferably in the range of 3 seconds to 3 hours, and more preferably in the range of 10 seconds to 1 hour.

By setting the heating time to fall within the above range, it is possible to sufficiently improve the productively of the circuit substrate 10 and more preferably progress the hardening reaction, and thereby more reliably improving the heat resistance property, the mechanical strength or the like of the circuit substrate 10.

According to the method for producing the circuit substrate of the present invention as described above, it is possible to produce the circuit substrate 10 which is downsized and in which the large current can flow at a high productivity. Next, description will be given to the method for producing the electronic component mounting substrate of the present invention.

<Electronic Component Connecting Step>

By connecting the electronic components 4 to the circuit substrate 10 obtained through the above steps, it is possible to obtain the electronic component mounting substrate 100 (1g). Namely, by connecting the first electronic component 4A to the first terminal 21 of the circuit substrate 10 and connecting the second electronic component 4B to the second terminal 22 of the circuit substrate 10, it is possible to obtain the electronic component mounting substrate 100.

The connecting of the electronic components 4 can be carried out by a brazing and soldering method with a brazing filler material. Examples of the brazing filler material include a solder material and a lead-free solder material. The lead-free solder material refers to a solder material substantially containing no lead or a solder material containing little lead (for example, a content percentage of lead is equal to or less than 0.1 percent by mass).

According to the method for producing the circuit substrate and the electronic component mounting substrate of the present invention as described above, it is possible to produce the circuit substrate and the electronic component mounting substrate which are downsized and in which the large current can flow at a high productivity.

Although the preferred embodiment of the present invention has been described, the present invention is not limited thereto. It is noted that a modification, an improvement or the like of the embodiment is also contained in the scope of the present invention as long as it can achieve the object of the present invention.

For example, although the circuit substrate includes the plurality of first terminals and the plurality of second terminals in the embodiment described above, the circuit substrate may include at least one first terminal and at least one second terminal in the present invention.

Further, in the embodiment described above, the exemplary case where there is a clear boundary surface between the first portion and the second portion is described. However, the boundary surface between the first portion and the second portion may be unclear in the present invention. Furthermore, the insulating part may has an area (mixed area) in which the constituent material for the first portion and the constituent material for the second portion are partially mixed with each other.

Further, in the embodiment described above, the case where the temporarily fixing member 6 has the sheet-like shape is described. However, the form of the temporarily fixing member 6 is not limited thereto and may have any shape.

The circuit substrate and the electronic component mounting substrate of the present invention may be produced any method and are not limited to a circuit substrate and an electronic component mounting substrate produced by the method as described above. For example, in the embodiment described above, the step for forming the first portion (the first hardening step) and the step for forming the high-insulating material layer (the second hardening step) are described as different steps, but these steps may be carried out in one step.

The second high-insulating composition supplying step and the second hardening step described above may be omitted as long as the method for producing the circuit substrate and the electronic component mounting substrate of the present invention includes the substrate preparing step, the metallic piece inserting step, the first high-insulating composition supplying step and the first hardening step. For example, it is possible to supply the first high-insulating material not only into the periphery of the metallic piece in the hole of the substrate (printed substrate) but also into a gap between the printed substrate and the supporting substrate, which is prepared preliminary, in the first high-insulating composition supplying step and form the first portion around the metallic piece and the high-insulating material layer between the supporting substrate and the printed substrate in the first hardening step.

Further, the method for producing the circuit substrate and the electronic component mounting substrate of the present invention may further include other steps (such as a pretreatment step, an aftertreatment step and an intermediate treatment) in addition to the steps described above.

Further, the circuit substrate and the electronic component mounting substrate of the present invention may have no supporting substrate and no high-insulating material layer.

What is claimed is:

1. A circuit substrate comprising:
a circuit layer, the circuit layer including:
a first terminal in which a current should flow,
a second terminal in which a current larger than the current flowing in the first terminal should flow, and
an insulating part,
wherein the insulating part has a first portion provided around the second terminal and a second portion, and
wherein an insulation property of the first portion is higher than an insulation property of the second portion.

2. The circuit substrate as claimed in claim 1, wherein the first portion of the insulating part is provided so as to surround an outer periphery of the second terminal.

3. The circuit substrate as claimed in claim 1, wherein the first terminal is a terminal for connecting a microcomputer.

4. The circuit substrate as claimed in claim 1, wherein the second terminal is a terminal for connecting an insulated gate bipolar transistor and/or a field effect transistor.

5. The circuit substrate as claimed in claim 1, further comprising a supporting substrate provided on a side of a lower surface of the circuit layer.

6. The circuit substrate as claimed in claim 5, further comprising a high-insulating material layer provided between the supporting substrate and the circuit layer, and
wherein the supporting substrate is formed of a metallic material.

7. The circuit substrate as claimed in claim 1, wherein a volume resistivity at a temperature of 25° C. of the first portion of the insulating part is in the range of 1×10⁷ to 1×10¹⁶ Ω·cm.

8. The circuit substrate as claimed in claim 1, wherein the first portion of the insulating part is formed of a mixture material, the mixture material containing:
a hardened material containing a phenol resin and an epoxy resin as a constituent component thereof,
a first inorganic filler having an average particle size of 2 to 300 μm, and
a second inorganic filler having an average particle size of 0.1 to 9.0 μm.

9. The circuit substrate as claimed in claim 1, wherein the second terminal penetrates through the circuit layer in a thickness direction thereof.

10. The circuit substrate as claimed in claim 1, wherein a distance between the first terminal and the second terminal which are adjacent to each other is in the range of 0.05 to 5.0 mm.

11. The circuit substrate as claimed in claim 1, wherein a width of the first portion in a planar view of the circuit substrate is equal to or more than 10 μm and less than 5 mm.

12. An electronic component mounting substrate comprising:
a circuit substrate defined in claim 1; and
electronic components respectively mounted to a first terminal and a second terminal of the circuit substrate.

13. A method for producing a circuit substrate including a circuit layer, the circuit layer including a first terminal in which a current should flow, a second terminal in which a current larger than the current flowing in the first terminal should flow and an insulating part having a first portion and a second portion, the method comprising:
preparing a substrate having the second portion as a part of the insulating part, the first terminal and a hole formed therein;
inserting a metallic piece to be the second terminal into the hole of the substrate;
supplying a first high-insulating composition into a periphery of the metallic piece in the hole; and
hardening the first high-insulating composition and forming the first portion as another part of the insulating part to obtain the circuit layer,
wherein an insulation property of the first portion is higher than an insulation property of the second portion.

14. The method for producing the circuit substrate as claimed in claim 13, further comprising supplying a second high-insulating composition so that a supporting substrate contacts with the circuit layer through the second high-insulating composition after hardening the first high-insulating composition, and
hardening the second high-insulating composition to form a high-insulating material layer.

15. The method for producing the circuit substrate as claimed in claim 14, wherein the supporting substrate is formed of a metallic material.

16. The method for producing the circuit substrate as claimed in claim 13, wherein inserting the metallic piece is carried out by inserting the metallic piece into the hole in a state that the metallic piece is temporarily fixed to a temporarily fixing member and contacting the temporarily fixing member with the substrate.

17. The method for producing the circuit substrate as claimed in claim 16, wherein inserting the metallic piece contains firmly contacting an entire of one surface of the substrate with the temporarily fixing member.

18. The method for producing the circuit substrate as claimed in claim 16, wherein the temporarily fixing member has a surface to be contacted with the metallic piece, and
wherein the surface to be contacted with the metallic piece is formed of a material having an adherence property.

19. The method for producing the circuit substrate as claimed in claim 18, wherein the material having the adherence property is a material whose adhesion strength with respect to an adherend reduces due to a hardening reaction.

20. The method for producing the circuit substrate as claimed in claim 16, wherein the temporarily fixing member has a sheet-like shape.

21. The method for producing the circuit substrate as claimed in claim 13, wherein inserting the metallic piece is carried out by fixing the metallic piece so that the metallic piece does not contact with the second portion of the insulating part.

22. The method for producing the circuit substrate as claimed in claim 13, wherein the first terminal is a terminal for connecting a microcomputer.

23. The method for producing the circuit substrate as claimed in claim 13, wherein the second terminal is a terminal for connecting an insulated gate bipolar transistor and/or a field effect transistor.

24. The method for producing the circuit substrate as claimed in claim 13, wherein the first high-insulating composition contains:
a phenol resin,
an epoxy resin,
a first inorganic filler having an average particle size of 2 to 300 μm, and
a second inorganic filler having an average particle size of 0.1 to 9.0 μm.

25. The method for producing the circuit substrate as claimed in claim 13, wherein a distance between the first terminal and the second terminal which are adjacent to each other is in the range of 0.05 to 5.0 mm.

26. The method for producing the circuit substrate as claimed in claim 13, wherein a width of the first portion of the insulating part in a planar view of the circuit substrate is equal to or more than 10 μm and less than 5 mm.

27. A circuit substrate produced by a method defined in claim 13.

28. An electronic component mounting substrate comprising:
a circuit substrate defined in claim 27; and
electronic components respectively mounted to a first terminal and a second terminal of the circuit substrate.
